(19) United States
(12) Patent Application Publication
(10) Pub. No.: US 2018/0097102 A1
(43) Pub. Date: Apr. 5, 2018

(54) SEMICONDUCTOR DEVICE AND METHOD OF MANUFACTURING A SEMICONDUCTOR DEVICE

(71) Applicant: Sanken Electric Co., Ltd., Saitama (JP)

(72) Inventors: Ryohei BABA, Saitama (JP); Toru YOSHIE, Saitama (JP); Tomonori HOTATE, Saitama (JP)

(73) Assignee: Sanken Electric Co., Ltd., Saitama (JP)

(21) Appl. No.: 15/283,149

(22) Filed: Sep. 30, 2016

(30) Foreign Application Priority Data
Sep. 30, 2016 (JP) 2016-193084

(51) Int. Cl. H01L 29/78; H01L 29/16; H01L 29/04; H01L 29/66

(52) U.S. Cl. CPC H01L 29/7813; H01L 29/66712; H01L 29/045; H01L 29/1608

(57) ABSTRACT

Provided is a semiconductor device that is good in switching characteristics and high in breakdown voltage in off state. The geometry of a corner of a trench T is provided with a rounded shape (a curved face geometry having a radius of curvature of R1) under the depth P1. In addition, assuming the thickness of a gate oxide film 21 on the side wall of the trench T in a right-left direction in figure is T0, and the thickness of the gate oxide film 21 in the central portion of the bottom part of the trench T in a vertical direction in figure is T1, the gate oxide film 21 is formed so as to meet T1>T0. The gate oxide film 21 is provided with a rounded shape (having a radius of curvature of R2) under the depth P2. In addition, the expression R2≦R1 is met.

### INCORPORATION BY REFERENCE

This application is based on and claims the benefit of priority from Japanese Patent Application No. 2016-193084 filed on Sep. 30, 2016, the entire contents of which are hereby incorporated by reference.

### BACKGROUND

The present invention relates to a structure of a semiconductor device in which a gate electrode is provided within a trench, and a method of manufacturing the same.

For switching operation at a large current, power MOSFETs are used, and in order to provide a large operating current, a trench MOSFET in which a gate electrode is provided within a trench in a semiconductor substrate is particularly preferably used. With trench gate power MOSFETs, in on state, a current flows between the source and the drain through a channel that has been induced in a trench side wall. As stated in Patent Document 1, in order to improve the switching characteristics of a power MOSFET, it is required to decrease the feedback capacitance Crss and the input capacitance Ciss, and reduce the on-resistance (the source-drain resistance in on state). Here, the feedback capacitance Crss is a gate-drain capacitance, and the input capacitance Ciss is a sum of the gate-source capacitance and the feedback capacitance Crss. Therefore, in order to realize good switching characteristics, it is required to reduce both the gate-source capacitance and the gate-drain capacitance. Here, as an example of a component of the gate-drain capacitance, there is a capacitance that is formed between the gate electrode and the trench bottom part. Such capacitance component is not directly related to the intrinsic MOS operation, being a parasitic capacitance that is incidentally formed in this structure, and thus it is particularly important to reduce this capacitance component for reduction of the Crss. If the gate oxide film is thickened, this capacitance component can be reduced, however, for reducing the on-resistance, it is required to thin the gate oxide film to some extent.

Therefore, with the power MOSFET disclosed in Patent Document 1, by locally thickening the oxide film (the gate oxide film) in the bottom part and the top part of a trench in the semiconductor substrate formed of silicon, which are portions that are not directly related to induction of a channel in the trench, the gate-drain capacitance and the gate-source capacitance are reduced. On the other hand, the gate oxide film on the side wall of the trench, which is a portion where the channel is formed, is thinned. With this structure, the parasitic capacitance can be reduced for reduction of the Ciss and Crss, and also the on-resistance can be reduced.

In addition, since, in particular, the power MOSFET is operated with a high voltage being applied across the source and the drain, it is also required that the source-drain (gate-drain) breakdown voltage in off state is high. In the case where a gate oxide film having a uniform film thickness is used, the dielectric breakdown of the gate oxide film tends to be easily generated especially in the bottom part of the trench, and thus, with the technology disclosed in Patent Document 1, by thickening the oxide film in the bottom part of the trench, such breakdown voltage is also increased.

Patent Document 1: Japanese Unexamined Patent Application Publication No. 2009-94484

In recent years, in order to make it possible for the power MOSFET to accommodate a still higher voltage, silicon carbide (SiC), which has wider band gap than silicon and can form an MOSFET in the same manner as silicon, is used in place of silicon. By using a semiconductor substrate that is formed of SiC to constitute a trench gate power MOSFET in the same manner, a power MOSFET that has high breakdown voltage and is more suited for a high voltage operation can be obtained.

Even in the case when SiC has been used, SiO₂ is used as a material for the gate oxide film in the same manner as in the case when silicon has been used, and in this case, particularly a problem of reduction in breakdown voltage resulting from a dielectric breakdown in the gate oxide film has been made remarkable. Therefore, in the case where SiC is used, and an operation at a high voltage is made, even with a structure in which the oxide film in the bottom part of the trench has been locally thickened as with the technology disclosed in Patent Document 1, the breakdown voltage has become insufficient.

On this point, an explanation will be given below. First, FIG. 6A shows a schematic section of a conventional semiconductor device (power MOSFET) with which the gate oxide film has a uniform thickness within the trench. Here, only the area around the trench in the power MOSFET is shown, being simplified. In the semiconductor substrate 90 that is used here, on an n⁻ layer 91 (a drift layer), which is of n type at a low donor concentration, being connected to the drain side, a p-layer 92 (a body layer) of p type, and an n⁺ layer 93 (a drain region), which is of n type at a high donor concentration, are sequentially formed from the bottom side. The trench T is formed so as to penetrate the n⁺ layer 93 and the p-layer 92 from the surface of the semiconductor substrate 90 and reach the p⁻ layer 91, and on the inner wall thereof, a gate oxide film 94 is formed with a uniform thickness. Here, the thickness of the gate oxide film 94 is set thin in the range in which good switching characteristics can be obtained with the on-current and the gate capacitance being taken into account. In the p-layer 92 that constitutes the side wall of the trench T, being opposed to the gate electrode 95, a channel is induced, and, in on state, a current flows across the n⁺ layer 93 and the n⁻ layer 91 through the channel and flows in the n⁻ layer 91 in a vertical direction in the figure. In off state (in which the gate voltage is equal to the ground voltage or the source voltage), there is formed no channel, and the n⁺ layer 93 and the n⁻ layer 91 are insulated from each other by the depletion layer. With this structure, the drain (the p⁻ layer 91), to which a high voltage is applied, and the gate electrode 95, which is provided with a ground potential, are in proximity to each other, and the breakdown voltage across these depends upon the dielectric breakdown of the gate oxide film 91, a place where there occurs a maximum degree of electric field concentration in the gate oxide film 94 being the region A in FIG. 6A. In other words, in the gate oxide film 94 at the corner of the bottom part of the trench T, where the geometry is abruptly changed, the dielectric breakdown is easily generated.

On the other hand, FIG. 6B shows a structure in which, as with the technology disclosed in Patent Document 1, the oxide film (the gate oxide film 94) in the trench T is set thin for the side wall of the trench T in the same manner as in FIG. 6A, while, for the bottom part of the trench T, being set thick in order to reduce the gate-drain capacitance. As described above, this structure can enhance the breakdown voltage, as compared to the structure in FIG. 6A. Therefore, a higher voltage than that for the structure in FIG. 6A was applied in off state in order to examine where a dielectric breakdown is generated, which has given a finding that the dielectric breakdown is generated in the region B in FIG. 6B. In other words, it has been found that, by thickening the gate oxide film in the bottom part of the trench T, the breakdown voltage is enhanced, however, in the corner area of the gate oxide film 94 in the bottom part of the trench T, a dielectric breakdown is still generated. In other words, even with the structure in FIG. 6B, that, in the bottom part of the trench T, a dielectric breakdown is locally generated has been the same as with the structure in FIG. 6A, in which the gate oxide film 94 is uniformly thin.

Therefore, with the technology disclosed in Patent Document 1, although the breakdown voltage is improved, it is restricted, resulting from a dielectric breakdown being locally generated in the gate oxide film 94 in the trench T, and this point has been the same as with the conventional technology. Therefore, the breakdown voltage on the technology disclosed in Patent Document 1 has been still unsatisfactory as that for power MOSFETs for high voltage.

Therefore, a semiconductor device that has good switching characteristics and is high in breakdown voltage in off state has been demanded.

The present invention has been made in view of such problems, and is intended to provide a semiconductor device with which the above-mentioned problems can be solved.

### SUMMARY

In order to solve the problems as described above, the present invention provides the following scheme:

According to an aspect of the present invention, there is provided a semiconductor device, using a semiconductor substrate having a first semiconductor region of a first conductivity type, a second semiconductor region of a second conductivity type opposite to the first conductivity type that has been formed on the first semiconductor region, and a third semiconductor region of the first conductivity type that has been formed on the second semiconductor region, the semiconductor device including: a trench that is formed from a surface of the third semiconductor region to such a depth that it penetrates through the third semiconductor region and the second semiconductor region, a gate oxide film that has been formed on an inner face of the trench, and a gate electrode that has been formed on the inner face of the trench through the gate oxide film, turning on or off of a current flowing between the first semiconductor region and the third semiconductor region being controlled with a potential of the gate electrode,

when viewed from a section perpendicular to an extending direction of the trench, assuming that the opening width of the trench is D, the radius of curvature R1 of a corner of a bottom part of the trench meeting an expression of D/10≦R1≦D/2, and, with the gate oxide film, the film thickness on the side of a bottom part within the trench being thicker than the film thickness on a side face within the trench, and being gradually increased from the corner of the bottom part of the trench toward a central portion of the trench.

According to another aspect of the present invention, there is provided a semiconductor device, in which the radius of curvature R2 of the gate oxide film that is formed at a corner of the bottom part of the trench is in the range of 0.1 to 1.0 times the radius of curvature R1.

According to another aspect of the present invention, there is provided a semiconductor device, in which the starting point P1 of a rounded shape that is formed with the radius of curvature R1 is disposed in a location in the semiconductor substrate that is deeper than the starting point P2 of a rounded shape that is formed with the radius of curvature R2.

According to another aspect of the present invention, there is provided a semiconductor device, in which, in a region that is adjacent to the trench in a top view, the gate electrode has a portion that is opposed to the surface of the semiconductor substrate through the gate oxide film that is formed thicker than the film thickness of the gate oxide film on the side face.

According to another aspect of the present invention, there is provided a semiconductor device, in which the semiconductor substrate is formed of silicon carbide (SiC).

According to another aspect of the present invention, there is provided a semiconductor device, in which the semiconductor substrate is formed of a 4H—SiC single crystal, and the surface of the semiconductor substrate has a plane orientation of [0001] C plane.

According to another aspect of the present invention, there is provided a method of manufacturing the semiconductor device, including a trench formation process for forming the trench in the semiconductor substrate, and a gate oxidation process for thermally oxidizing the semiconductor substrate after the trench formation process, thereby forming the gate oxide film having a film thickness on the side of the bottom part that is larger than the film thickness of the gate oxide film on the side face.

According to another aspect of the present invention, there is provided a method of manufacturing a semiconductor device, in which, between the trench formation process and the gate oxidation process, a rounded shape formation process for performing a heat treatment in a non-oxidation atmosphere to provide the section of a corner of the bottom part with a rounded shape is performed.

The present invention is schemed as described above, whereby a semiconductor device that is good in switching characteristics and high in breakdown voltage in off state.

### BRIEF DESCRIPTION OF THE DRAWINGS

FIG. 1 is a sectional view of a semiconductor device according to an embodiment of the present invention;

FIG. 2 is a sectional view illustrating the structure of the bottom part of a trench in a semiconductor device according to the embodiment of the present invention in an enlarged manner;

FIG. 3A is a process sectional view (a first of a set of figures) illustrating one example of manufacturing method for the semiconductor device according to the embodiment of the present invention;

FIG. 3B is a process sectional view (a second of a set of figures) illustrating one example of manufacturing method for the semiconductor device according to the embodiment of the present invention;

FIG. 3C is a process sectional view (a third of a set of figures) illustrating one example of manufacturing method for the semiconductor device according to the embodiment of the present invention;

FIG. 3D is a process sectional view (a fourth of a set of figures) illustrating one example of manufacturing method for the semiconductor device according to the embodiment of the present invention;

FIG. 3E is a process sectional view (a fifth of a set of figures) illustrating one example of manufacturing method for the semiconductor device according to the embodiment of the present invention;

FIG. 4F is a process sectional view (a sixth of a set of figures) illustrating one example of manufacturing method for the semiconductor device according to the embodiment of the present invention;

FIG. 4G is a process sectional view (a seventh of a set of figures) illustrating one example of manufacturing method for the semiconductor device according to the embodiment of the present invention;

FIG. 4H is a process sectional view (an eighth of a set of figures) illustrating one example of manufacturing method for the semiconductor device according to the embodiment of the present invention;

FIG. 5 is a sectional view of a variation of the semiconductor device according to the embodiment of the present invention;

FIG. 6A is a figure (a first of a set of figures) schematically illustrating a place where an electric field concentration is generated in the gate oxide film in a conventional semiconductor device of trench gate type; and

FIG. 6B is a figure (a second of a set of figures) schematically illustrating a place where an electric field concentration is generated in the gate oxide film in the conventional semiconductor device of trench gate type.

### DETAILED DESCRIPTION

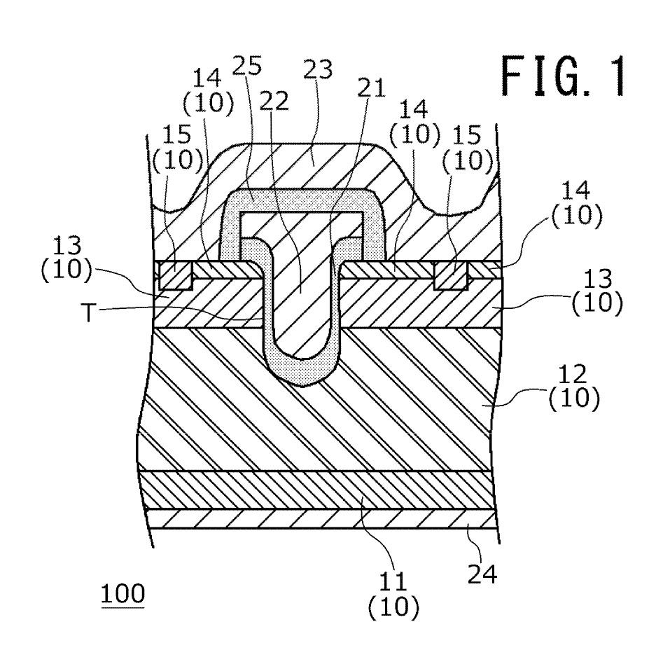

Hereinbelow, a semiconductor device according to an embodiment of the present invention will be explained. FIG. 1 is a sectional view of such semiconductor device 100. This semiconductor device 100 is a power MOSFET of trench gate type, using a semiconductor substrate 10 in which there are formed an n⁺ layer (a drain layer) 11 of n type (a first conductivity type), in which a doner has been doped at a high concentration; an n⁻ layer (a drift layer: a first semiconductor region) 12, in which a doner has been doped at a low concentration; a p layer (a body layer: a second semiconductor layer region) 13 of p type (a second conductivity type), in which an acceptor has been doped at a low concentration; an n⁺ layer (a source region: a third semiconductor region) 14, in which a doner has been doped at a high concentration; and a p⁺ layer 15, in which an acceptor has been doped at a high concentration, and the whole of which is formed of SiC. The crystal form of SiC is 4H—SiC of hexagonal crystal system, and the surface of the semiconductor substrate 10 has a plane orientation of [0001] C plane.

In addition, in this semiconductor substrate 10, a trench T, which reaches the n⁻ layer 12 from the surface thereof (the n⁺ layer 14), is formed, and in FIG. 1, a section perpendicular to an extending direction of the trench T is shown. In addition, in the state in which, on the inner face of the trench T, there is formed a gate oxide film 21, which is made up of SiO₂, a gate electrode (control electrode) 22 is formed so as to embed the internal portion of the trench T.

In addition, on the side of the top face (the surface) of the semiconductor substrate 10, a source electrode (a first main electrode) 23, which is connected to the n⁺ layer 14 and the p⁺ layer 15, is formed, and on the side of the bottom face (the rear surface), a drain electrode (a second main electrode) 24, which is in contact with the n⁺ layer 11 over the entire rear surface, is formed. On the side of the top face, the gate electrode 22 and the source electrode 23 are insulated from each other by an interlayer insulating layer 25, which is formed of SiO₂. As described above, turning on/off of a current flowing across the source electrode 23 and the drain electrode 24 is controlled by a voltage applied to the gate electrode 22, and a current due to this voltage flows in a vertical direction in the region providing a side wall of the trench T in the p layer 13, and in the p⁻ layer (the drift layer) 12.

In addition, actually, a plurality of trenches T are formed in parallel in a right-left direction in FIG. 1 in the semiconductor substrate 10, and corresponding to the trenches T, a plurality of structures in FIG. 1 are formed. In this case, the source electrode 23 and the drain electrode 24 are common among these structures, and the gate electrodes 22 in the respective structures are electrically connected to one another outside of the range shown in the figure. Therefore, a plurality of trench gate power MOSFETs having a structure in FIG. 1 are connected in parallel, whereby a large current can be caused to flow across the common source electrode 23 and drain electrode 24, the on-off state being determined by the voltage that is applied to the gate electrode 22. Normally, the source electrode 23 is provided with a ground potential, and to the drain electrode 24, a high voltage of 500 V or over is applied for use. The potential of the source electrode 23 is zero (a ground potential) in off state, while, in on state, being 10 V or so. The above-mentioned matters are the same as with the power MOSFET of trench gate type that has been conventionally known.

This semiconductor device 100 features a sectional geometry of the trench T, and a sectional geometry of the gate oxide film 21, which is formed on the inner face thereof. The geometry of the trench T on the side of the bottom part in FIG. 1 is shown, being enlarged. With this structure, both corners of the bottom part in the sectional geometry of the trench T are provided with a rounded shape. In addition, together with this, both corners of the bottom part of the gate oxide film 21, which is formed on the inner face of the trench T having this geometry, are also provided with a rounded shape, however, the film thickness thereof is not uniform, but is larger on the side of the bottom face.

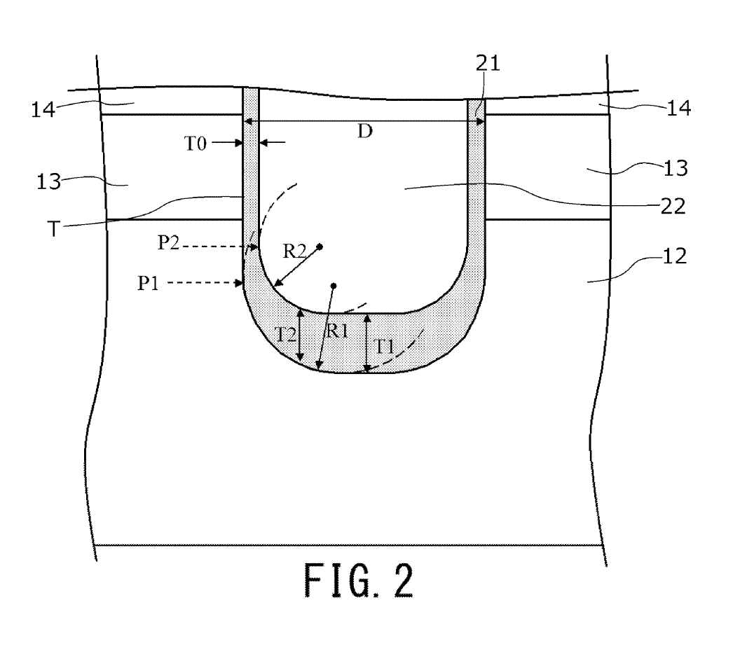

In FIG. 2, there is given a detailed depiction for only the left side of the bottom face of the trench T, however, actually, the structure of the trench T and the internal portion thereof are symmetrical about the center line of the trench T. First, the geometry on the side of the corner of the trench T is provided with a rounded shape under the depth P1, in other words, a curved face having a radius of curvature of R1. The depth P1 is located in the n⁻ layer 12 under the p layer 13. In addition, assuming that the thickness of the gate oxide film 21 on the side wall of the trench T along the right-left direction in the figure (a direction perpendicular to the thickness direction of the semiconductor substrate 10) is T0, and the thickness of the gate oxide film 21 in the central portion of the bottom part of the trench T along the vertical direction in the figure (the thickness direction of the semiconductor substrate 10) is T1, the gate oxide film 21 is formed such that an expression of T1>T0 is met, in other words, the bottom part of the gate oxide film 21 is formed thicker than the side wall in the trench T. The gate oxide film 21 having a thickness of T0 as the side wall of the trench T is a portion that directly contributes to formation of a channel in the MOS structure, and the value of T0 is set in an appropriate manner according to such characteristic. Specifically, the value of T0 is greater than or equal to 30 nm and less than or equal to 100 nm. On the other hand, the value of T1 is greater than or equal to 50 nm and less than or equal to 400 nm so long as an expression of T1>T0 is met.

In addition, corresponding to that the geometry of the trench T on the side of the bottom face is provided with a rounded shape (having a radius of curvature of R1) as described above, the gate oxide film 21 is provided with a rounded shape (having a radius of curvature of R2) under the depth P2. The depth P2 is also located in the p⁻ layer 12 under the p layer 13, however, the depth P2 is shallower than the depth P1, in other words, located on the side closer to the p layer 13. In addition, an expression of R2≦R1 is met. Therefore, assuming that the thickness along a vertical direction of the gate oxide film 21 in a location away from the central portion of the bottom part of the trench T is T2, an expression of T2<T1 is met. However, T2>T0 is met, and thus T0<T2<T1 is met.

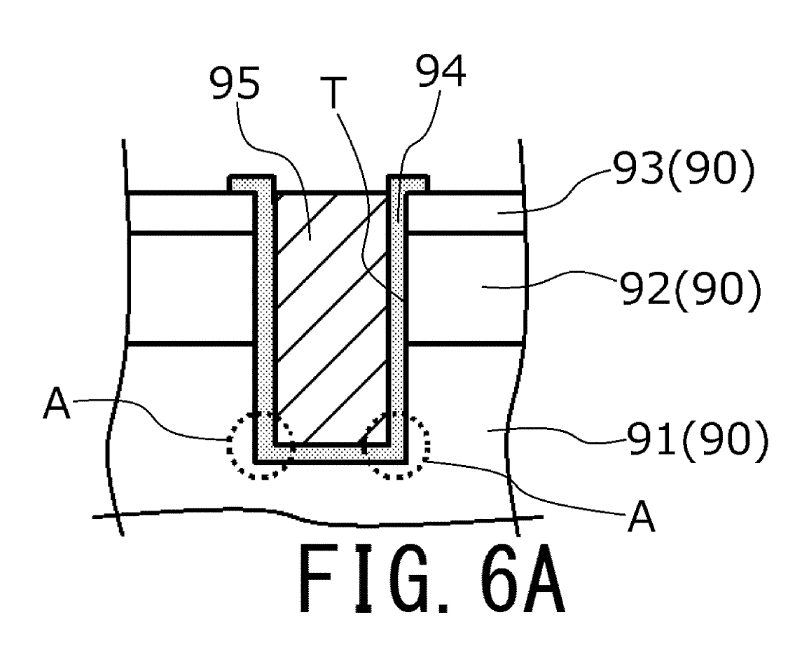

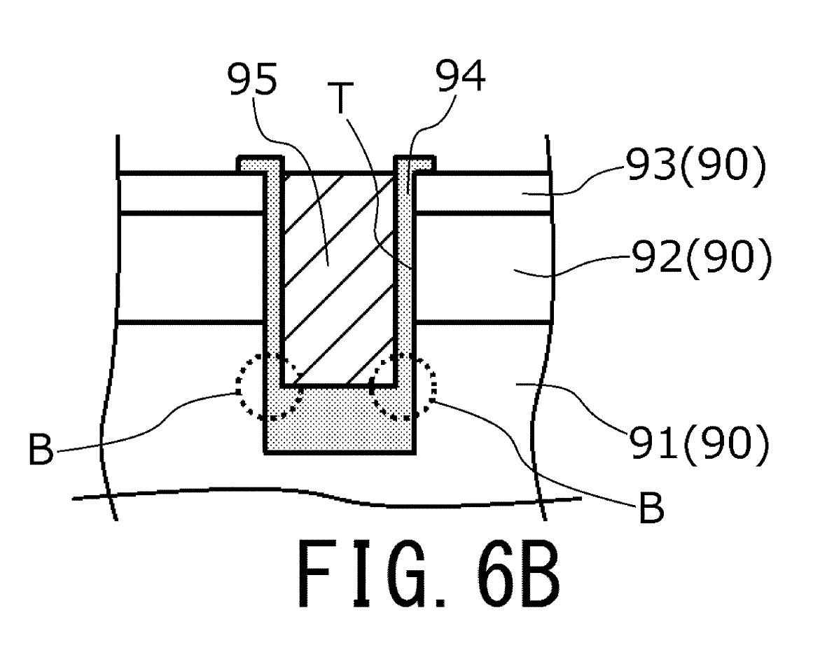

Therefore, also with this semiconductor device 100, in the same manner as with the structure disclosed in Patent Document 1, the capacitance between the gate electrode 22 and the n⁻ layer 12 in the bottom part of the trench T is reduced, whereby the gate-drain capacitance can be reduced. In addition, with this structure, the change in sectional geometry of the trench T and that in sectional geometry of the gate oxide film 21 are made gradual, whereby an electric field concentration that has been explained with FIG. 6A and FIG. 6B is difficult to be generated. In other words, with the above-described configuration, in the sectional geometry of the trench T and the gate oxide film 21 (the gate electrode 22) in the internal portion thereof, a place where the geometry is abruptly changed is eliminated, and on the side of the bottom part of the trench T, the gate oxide film 21 can be particularly thickened. Thereby, formation of a place where an electric field concentration is easy to be generated in the gate oxide film 21 as shown in FIG. 6A and FIG. 6B can be suppressed. Thereby, compared to the structure in FIG. 6B, the breakdown voltage can be further increased. On the other hand, the gate oxide film 21 on the side wall of the trench T can be maintained to be thinner than the bottom part. Therefore, good switching characteristics and a high breakdown voltage can be obtained.

Here, in FIG. 2, increasing the value of R1 will make the above-mentioned effect more remarkable, however, in the case where, assuming that the opening width of the trench T is D, an expression of R1>D/2 holds, the geometry of the central portion of the bottom face of the trench T may be sharp (abruptly changed). In order to make the sectional geometry within the trench T gradual for avoidance of such an abrupt change, it is preferable that the value of R1 meet the expression D/10≦R1≦D/2 such that a flat portion is provided in the central portion of the bottom face. Corresponding to this, it is preferable that the value of R2 be equal to or smaller than R1, specifically, be in the range of 0.1 to 1.0 times the value of R1, more preferably the value of R2 being in the range of 0.5 to 1.0 times the value of R1, and still more preferably being in the range of 0.7 to 1.0 times the value of R1. In addition, as described above, the depth P2 is shallower than the depth P1, however, the difference between these (the difference in depth) is preferably 70% or so of the maximum thickness T1 in the bottom part of the gate oxide film 21. In the case where, as described above, the value of T1 is in the range of from 50 nm to 400 nm, the difference between the depths P2 and P1 will be in the range of 30 nm to 280 nm or so. The opening width D of the trench T is in the range of 2 μm to 1.5 μm, and typically 1 μm or so. The depth of the trench T is not directly relates to the above-described structure, however, it is typically 1 μm or so, and is set in an appropriate manner accordingly to the thickness of the p layer 13 and that of the n⁺ layer 14.

With the above-described configuration, it is allowed that, while the gate oxide film 21 on the side wall in the trench T being maintained to be thin, the gate oxide film 21 on the side of the bottom face is thickened, and the change in geometry of the entire structure within the trench T is made gradual, thereby occurrence of a local electric field concentration in the gate oxide film 21 being suppressed.

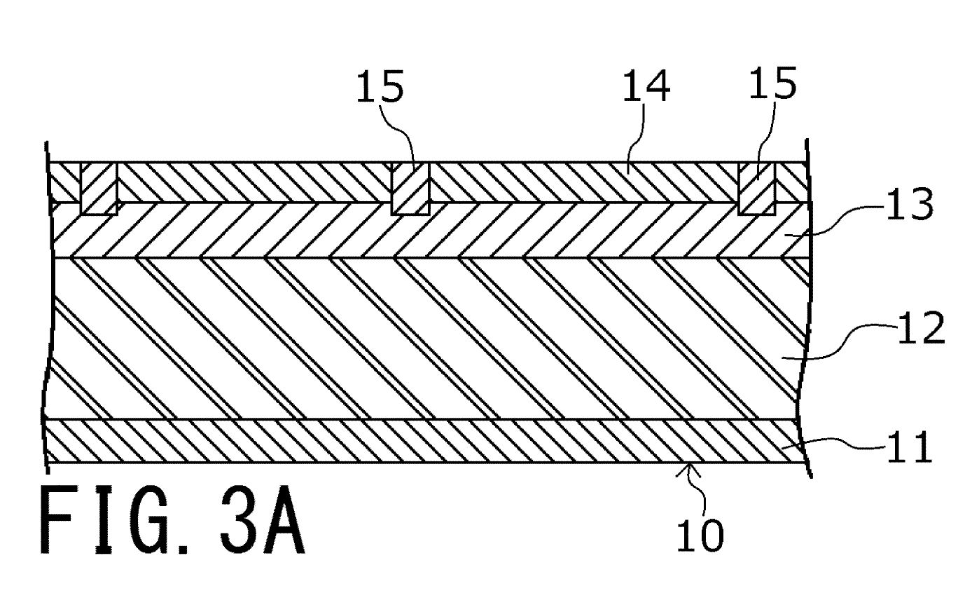

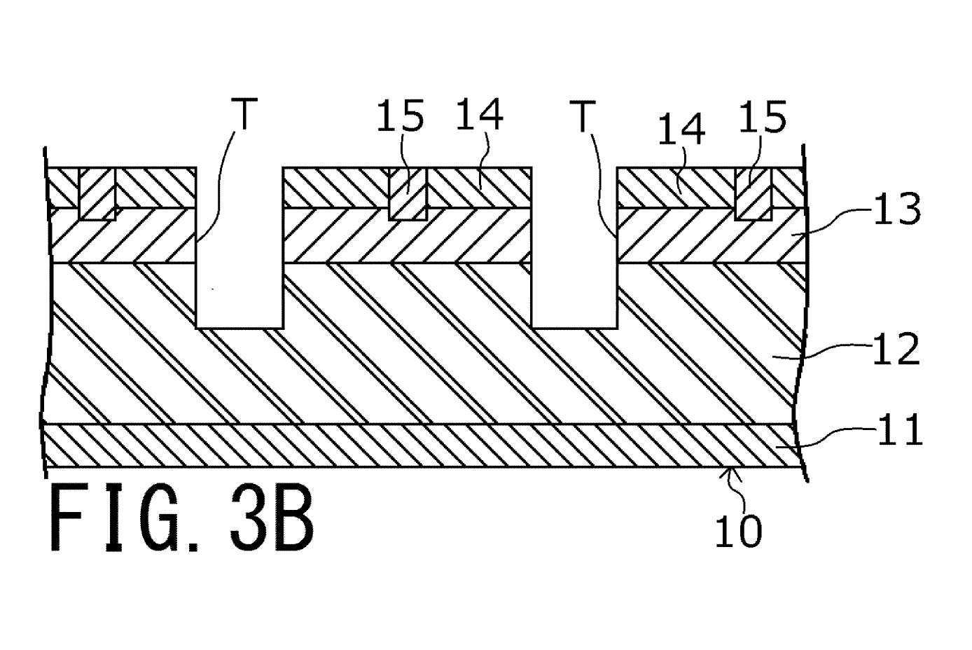

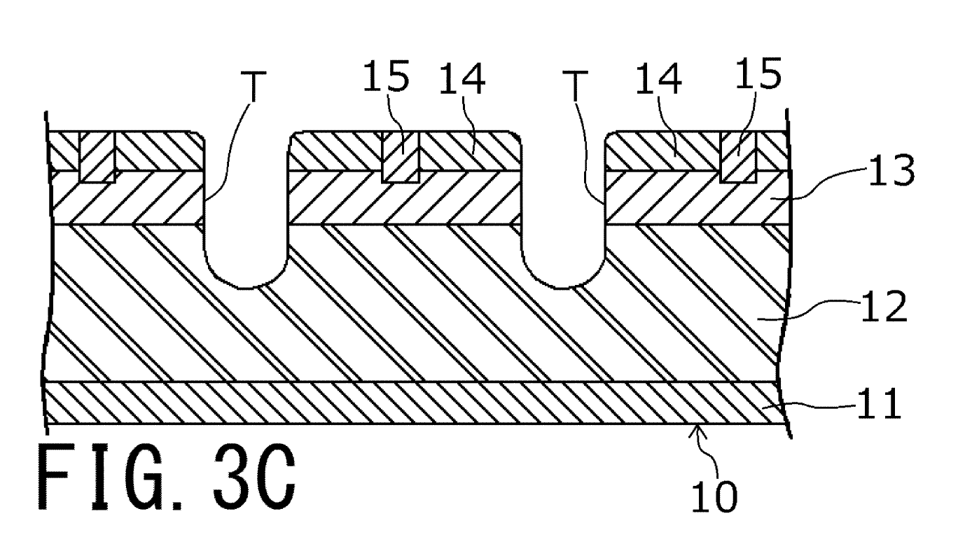

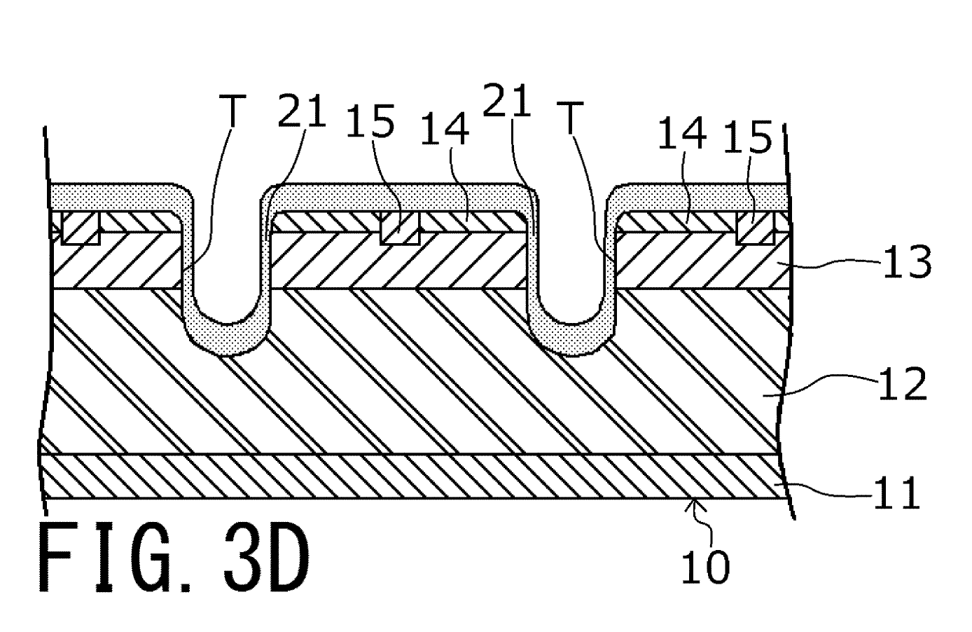

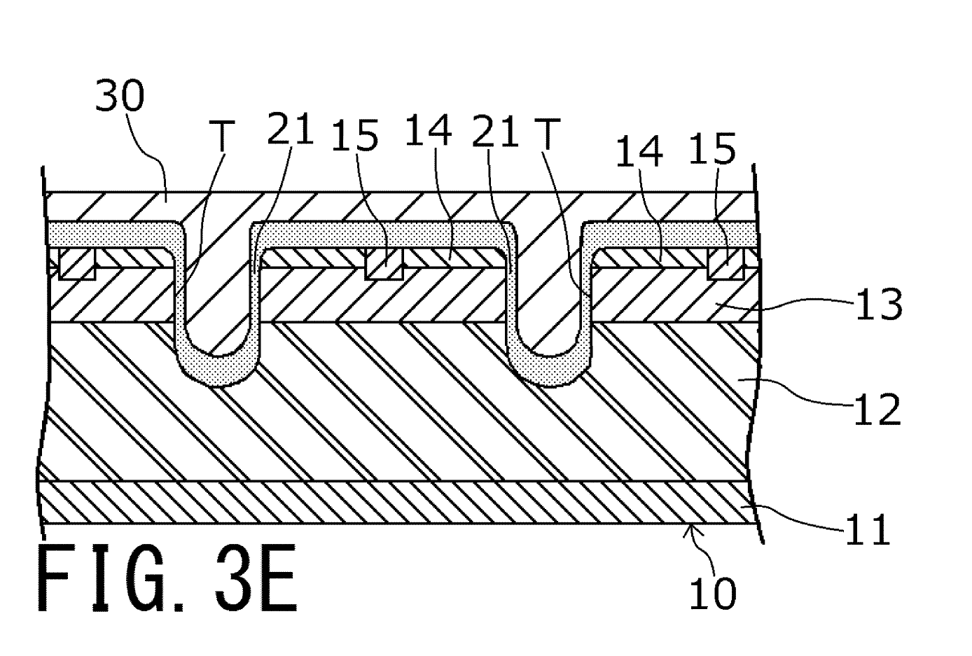

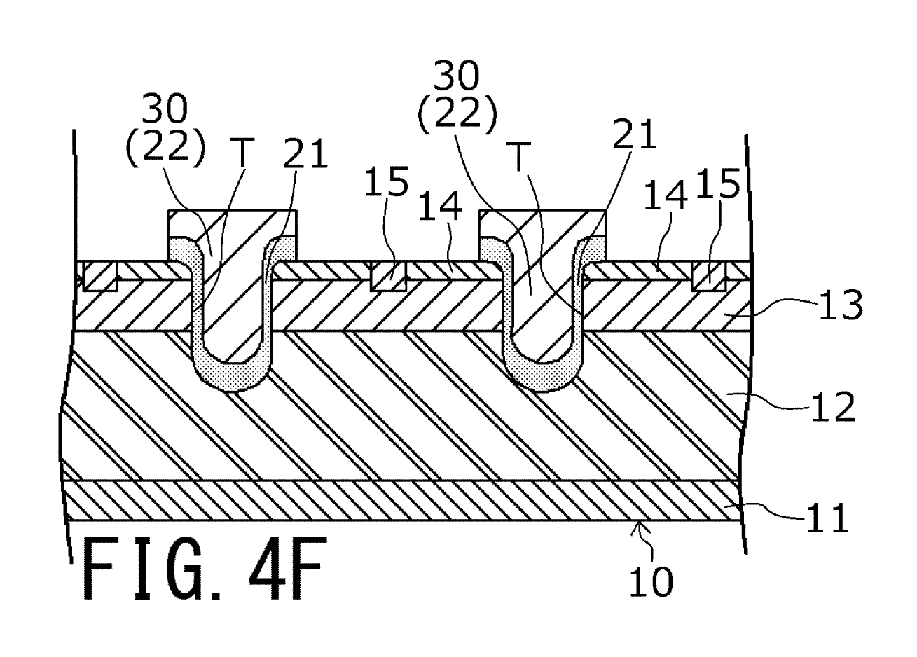

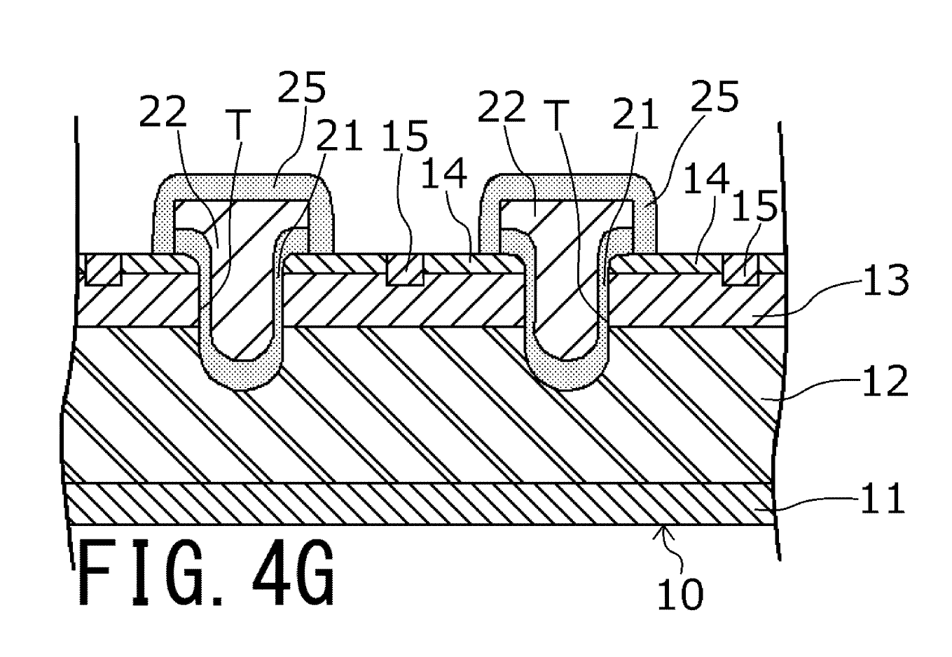

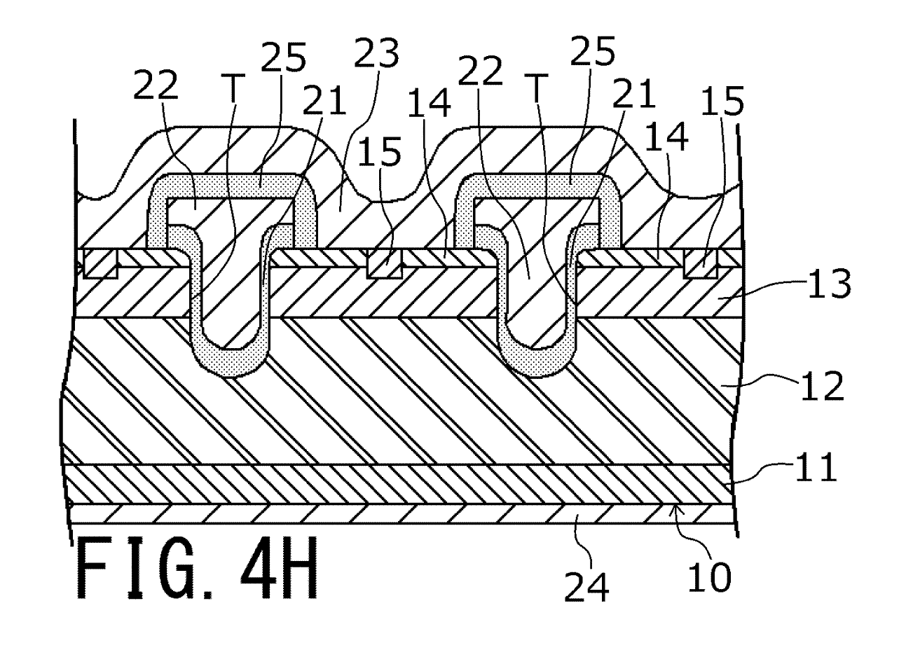

In addition, the above-described semiconductor device 100 can be easily manufactured as explained hereinbelow. FIG. 3A to FIG. 3E and FIG. 4F to FIG. 4H are process sectional views illustrating the manufacturing processes. Here, there is shown a section of a portion where two structures in FIG. 1 are formed in parallel.

First, as shown in FIG. 3A, a semiconductor substrate 10 in which an n⁺ layer (a drain layer) 11, an p⁻ layer (a drift layer) 12, a p layer 13, an n⁺ layer 14, and a p⁺ layer 15 are formed is prepared. The semiconductor substrate 10 is formed of a single crystal of 4H—SiC. The n⁻ layer 12 and the p layer 13 can be formed by sequentially performing an epitaxial growth or an impurity diffusion or an ion implantation on the n⁺ layer 11. In addition, the n⁺ layer 14 and the p⁺ layer 15 can be locally formed on the surface of the semiconductor substrate 10 by locally performing an impurity diffusion or an ion implantation into the p layer 13. In the case where ion implantation is used to form the respective layers, it is necessary to perform a heat treatment for activating the doner and the acceptor after the ion implantation, however, at this stage, only the ion implantation may be performed, and the heat treatment may be later conducted in a batch.

Next, as shown in FIG. 3B, a trench T is formed (a trench formation process). This process is performed by locally dry etching the SiC material with, for example, a photoresist layer being used as a mask. The dry etching is performed anisotropically, thereby the semiconductor substrate 10 being perpendicularly dug down from the surface. In this case, the opening width of the trench T depends upon the opening of the photoresist, and the depth can be controlled with the etching time, being adjusted such that the bottom face of the trench T is brought into the n⁻ layer 12. At this stage, the sectional geometry of the trench T is substantially rectangular, and the radius of curvature R1 of both corners in the bottom part in FIG. 2 is close to zero, both corners having a geometry that is close to a right angle.

Next, as shown in FIG. 3C, by performing a heat treatment at a high temperature in a non-oxidation atmosphere, a reflow state can be generated in the SiC material constituting the semiconductor substrate 10 to provide both corners in the bottom part of the trench T with a rounded shape (a rounded shape formation process). The radius of curvature that is to be provided in this process can be adjusted with the time for heat treatment.

Thereafter, as shown in FIG. 3D, by performing a heat treatment in an oxidation atmosphere, a gate oxide film 21 can be formed over the entire face of the semiconductor substrate 10, including the internal portion of the trench T (a gate oxidation process). In this process, the thermal oxidation speed for the 4H—SiC single crystal that forms the semiconductor substrate 10 has a plane orientation dependency, and especially the thermal oxidation speed for [0001] C plane is high, when compared with the other planes (for example, a plane orthogonal thereto). Therefore, as shown in FIG. 2, the gate oxide film 21 can be formed to be thick on the bottom part and to be thin on the side wall in the internal portion of the trench T. In this process, the portions on the sides of both corners of the trench T are provided with a rounded shape as described above, and therefore in these portions, the plane orientation is gradually changed from [0001] C plane. Therefore, in accordance with this, the film thickness of the gate oxide film 21 is gradually changed accordingly to the geometry of the trench T such that it is thick on the side of the central portion in the bottom part, while being gradually thinned toward the side of both corners. In this way, the sectional geometry of the gate oxide film 21 shown in FIG. 1 and FIG. 2 can be realized.

Thereafter, as shown in FIG. 3E, a conductive polycrystalline silicon layer 30, in which an impurity has been doped at a high concentration, is formed on the entire face of the semiconductor substrate 10 by the CVD method. In this process, under such conditions that the inside of the trench T is embedded with the polycrystalline silicon layer 30, the polycrystalline silicon layer 30 is deposited sufficiently thick.

Thereafter, as shown in FIG. 4F, the polycrystalline silicon layer 30 and the gate oxide film 21 are etched such that these are left only in the area around the trench T in a plan view. This process is performed by forming a mask, such as a photoresist, in the region where these are to be left, and sequentially etching the polycrystalline silicon layer 30 and the gate oxide film 21. The polycrystalline silicon layer 30 that has been left thereby provides a gate electrode 22. To the geometry of the gate electrode 22 in the trench T, the geometry of the gate oxide film 21 in the trench T is reflected.

Thereafter, as shown in FIG. 4G, an interlayer insulating layer 25 is locally formed so as to cover the gate electrode 22 and the gate oxide film 21 that are exposed on the surface side of the semiconductor substrate 10. The interlayer insulating layer 25 is formed of SiO₂ as the gate oxide film 21, and is provided with a morphology as shown in FIG. 4G by forming it by the CVD method on the entire face, and then etching away the unnecessary portion in the same manner as in the process explained with reference to FIG. 4F.

Thereafter, as shown in FIG. 4H, on the surface side and the rear surface side of the semiconductor substrate 10, a source electrode 23 and a drain electrode 24 are formed on the entire face, respectively. The source electrode 23 and the drain electrode 24 are formed of a metallic material that makes ohmic contact with the layer to which these are each brought into contact. As described above, the plurality of gate electrodes 22 that are formed in parallel are electrically connected to one another outside of the range shown in the figure.

By the above-described processes, the semiconductor device 100 in FIG. 1 can be manufactured. In the above-explained example, the rounded shape formation process has been performed in order to provide both corners of the bottom face of the trench T with a rounded shape after the trench formation process, however, the rounded shape can also be provided by adjusting the dry etching conditions in the trench formation process. In addition, wet etching, or the like, can also be used to provide the rounded shape.

In addition, the above-explained example, by selecting the plane orientation of the semiconductor substrate 10, the film thickness distribution (the sectional geometry) of the gate oxide film 21 as described above has been realized, however, by, for example, using the thermal oxidation method together with some other SiO₂-film deposition method (the CVD method, or the like), the same film thickness distribution of the gate oxide film 21 as described above can also be realized. However, especially in the case where SiC is used as the material, only by specifying the plane orientation of the semiconductor substrate 10 to be [0001] C plane, the above-described structure can be particularly easily formed.

With the structure in FIG. 1, the gate oxide film 21 is thick for the upward directed face, while being thin for the laterally directed face (the side face of the trench T). In the rounded shape formation process, the trench T is provided with a rounded shape not only on the side of the bottom face, but also on the side of the opening top part of the trench T. Therefore, in the portion around the trench T on the side of the top face of the semiconductor substrate 10 or in the vicinity of the upper end part of the trench T in the semiconductor substrate 10, the gate oxide film 21 is formed thick in the same manner as the bottom face of the trench T. Therefore, in such portions, the gate electrode 22 is opposed to the n⁺ layer 14 through a thick gate oxide film 21. Therefore, even in the case where the gate electrode 22 is formed up to the side of the top part of the trench T in this way, the gate-drain capacitance is suppressed from being increased.

In this way, by providing the gate electrode 22 also on the side of the top part of the trench T, a wiring structure that uses this portion can be formed, whereby the degree of freedom in wiring design can be increased. With the above-described structure, even in such a case, the increase in gate-source capacitance can be suppressed.

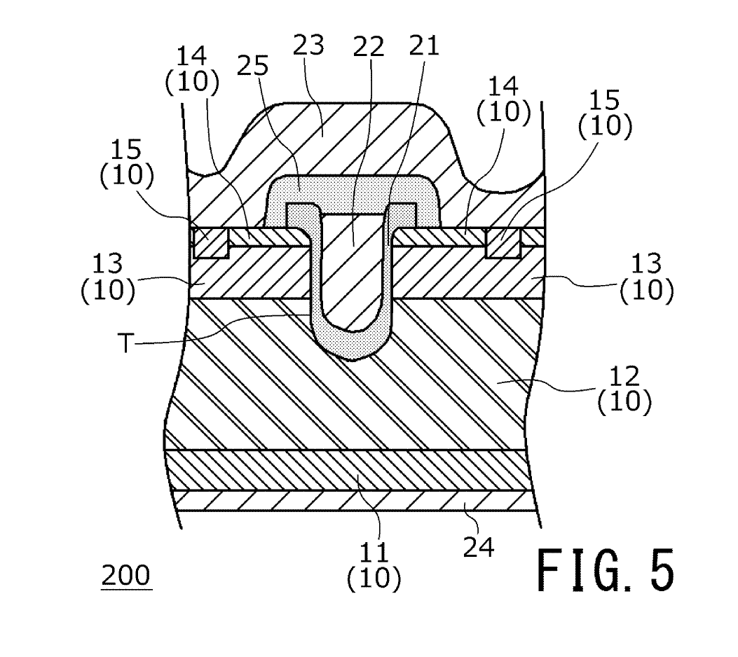

Instead of forming the gate electrode 22 on the side of the top part of the trench T in this way, the gate electrode 22 may be provided only on the side of the internal portion of the trench T. FIG. 5 is a sectional view showing a semiconductor device 200 (a variation of the above-described embodiment), which is provided with such a structure, in correspondence to FIG. 1. With this structure, the structure on the side of the bottom part of the gate electrode 22 is the same as in FIG. 1, thereby the gate-drain capacitance being small in spite of the geometry of the top part of the gate electrode 22, and this structure is also the same in that the electric field concentration in the gate oxide film 21 is suppressed. The structure in FIG. 5 can be realized by forming a polycrystalline silicon layer 30 (FIG. 3E), then etching back it, and performing the process in FIG. 4G and the subsequent in the same manner.

For the structure in FIG. 1 (Example) with which the width D of the trench T is specified to be 1 μm, and the gate oxide film thicknesses T0 and T1 are specified to be T0=50 nm and T1=300 nm, with the values of R1 and R2 being specified to be R1=0.35 μm and R2=0.30 μm, and the structure in FIG. 6A that is provided with the same values of D and T0 (Comparative Example: T1=T0, and R1=R2≅0), a simulation about the intensity of electric field was conducted to find that, in Example, there occurred no electric field concentration in any specific place, the maximum intensity of electric field in the gate oxide film in off state being 3.0 MV/cm (which corresponds to a breakdown voltage of 1500 V). On the other hand, in Comparative Example, an electric field concentration as shown in FIG. 6A was generated, the maximum intensity of electric field in the gate oxide film in off state (which was generated at places A in FIG. 6A) being 5.0 MV/cm (which corresponds to a breakdown voltage of 900 V). In other words, it was verified that the structure of the semiconductor device according to the embodiment of the present invention improves the breakdown voltage. Further, the structure of the portion where a channel is formed is unchanged between Example and Comparative Example, and in Example, the gate-drain capacitance is lowered, as compared to that in Comparative Example, thereby the switching characteristics being improved.

In the above example, there has been a discussion about the case where SiC, with which the intensity of electric field in the gate oxide film 21 within the trench T has a particularly significant effect on the breakdown voltage in off state, is used, however, even in the case where the semiconductor substrate is formed of any other material, it is clear that, for any element of trench gate type that is required to have a high breakdown voltage, the above configuration is also effective. In this course, the plane orientation of a semiconductor substrate that allows the film thickness distribution of the gate oxide film as described above to be easily realized can be set in accordance with the material.

In addition, in the above example, there has been given a discussion about the power MOSFET of n-channel type, however, it is also possible to adopt the same configuration for the p-channel type. In this case, by using a first semiconductor region, a second semiconductor region, a third semiconductor region, and the like, with which the conductivity type has been all reversed to that of the above-mentioned ones, the same effect can be obtained.

Reference numeral 10, 90 denotes a semiconductor substrate; 11 an n⁺ layer (a drain layer); 12, 91 an p⁻ layer (a drift layer: a first semiconductor region); 13, 92 a p layer (a body layer: a second semiconductor region); 14, 93 an n⁺ layer (a source region: a third semiconductor region); 15 a p⁺ layer; 21, 94 a gate oxide film; 22, 95 a gate electrode (a control electrode); 23 a source electrode (a first main electrode); 24 a drain electrode (a second main electrode); 25 an interlayer insulating layer; 30 a polycrystalline silicon layer; 100, 200 a semiconductor device (a power MOSFET); and T a trench.

What is claimed is:

1. A semiconductor device, using a semiconductor substrate having
a first semiconductor region of a first conductivity type,
a second semiconductor region of a second conductivity type opposite to the first conductivity type that has been formed on the first semiconductor region, and
a third semiconductor region of the first conductivity type that has been formed on the second semiconductor region,
the semiconductor device comprising:
a trench that is formed from a surface of the third semiconductor region to such a depth that it penetrates through the third semiconductor region and the second semiconductor region,
a gate oxide film that has been formed on an inner face of the trench, and
a gate electrode that has been formed on the inner face of the trench through the gate oxide film,
turning on or off of a current flowing between the first semiconductor region and the third semiconductor region being controlled with a potential of the gate electrode,
when viewed from a section perpendicular to an extending direction of the trench,
assuming that the opening width of the trench is D, the radius of curvature R1 of a corner of a bottom part of the trench meeting an expression of D/10≦R1≦D/2, and,
with the gate oxide film,
the film thickness on the side of a bottom part within the trench being thicker than the film thickness on a side face within the trench, and being gradually increased from the corner of the bottom part of the trench toward a central portion of the trench.

2. The semiconductor device according to claim 1, wherein the radius of curvature R2 of the gate oxide film that is formed at a corner of the bottom part of the trench is in the range of 0.1 to 1.0 times the radius of curvature R1.

3. The semiconductor device according to claim 2, wherein the starting point P1 of a rounded shape that is formed with the radius of curvature R1 is disposed in a location in the semiconductor substrate that is deeper than the starting point P2 of a rounded shape that is formed with the radius of curvature R2.

4. The semiconductor device according to claim 1, wherein,
when viewed from a section perpendicular to an extending direction of the trench,
the film thickness of the gate oxide film on the side face is in the range of 30 nm to 100 nm, and
the film thickness of the gate oxide film in the central portion of the bottom part of the trench is in the range of 50 nm to 400 nm.

5. The semiconductor device according to claim 1, wherein,
in a region that is adjacent to the trench in a top view,
the gate electrode has a portion that is opposed to the surface of the semiconductor substrate through the gate oxide film that is formed thicker than the film thickness of the gate oxide film on the side face.

6. The semiconductor device according to claim 1, wherein the semiconductor substrate is formed of silicon carbide (SiC).

7. The semiconductor device according to claim 6, wherein the semiconductor substrate is formed of a 4H—SiC single crystal, and the surface of the semiconductor substrate has a plane orientation of [0001] C plane.

8. A method of manufacturing a semiconductor device that is claimed in claim 7, comprising:
a trench formation process for forming the trench in the semiconductor substrate, and
a gate oxidation process for thermally oxidizing the semiconductor substrate after the trench formation process, thereby forming the gate oxide film having a film thickness on the side of the bottom part that is larger than the film thickness of the gate oxide film on the side face.

9. The method of manufacturing a semiconductor device according to claim 8, wherein,
between the trench formation process and the gate oxidation process,
a rounded shape formation process for performing a heat treatment in a non-oxidation atmosphere to provide the section of a corner of the bottom part with a rounded shape is performed.
